(19) United States
(12) Patent Application Publication
(10) Pub. No.: US 2008/0018347 A1
(43) Pub. Date: Jan. 24, 2008

(54) Capacitance type sensor

(75) Inventor: Hideo Morimoto, Yamatokoriyama-shi (JP)

Correspondence Address: OSHA LIANG L.L.P., 1221 MCKINNEY STREET, SUITE 2800, HOUSTON, TX, 77010, US

(73) Assignee: NITTA CORPORATION, Osaka (JP)

(21) Appl. No.: 11/825,306

(22) Filed: Jul. 5, 2007

(30) Foreign Application Priority Data
Jul. 11, 2006 (JP) JP2006-190713

(51) Int. Cl. G01R 27/26

(52) U.S. Cl. 324/662

(57) ABSTRACT

In a capacitance type sensor, capacitive elements are formed between a displacement electrode 104 and capacitance electrodes E1 and E2. When an external force is applied, the displacement electrode 104 is displaced to come into contact with a switch electrode E3 or E4 kept at a ground potential. The displacement electrode 104 is further displaced with being in contact with the switch electrode E3 or E4. When the displacement of the displacement electrode 104 changes the distances from the capacitance electrodes E1 and E2, the capacitance values of the capacitive elements change. Based on the changes, the force is detected.

### CROSS REFERENCE TO RELATED APPLICATION

This application claims priority from Japanese Patent Application No. 2006-190713 filed on Jul. 11, 2006.

### BACKGROUND OF THE INVENTION

1. Field of the Invention

The present invention relates to a capacitance type sensor suitable for detecting a force.

2. Description of Related Art

A capacitance type sensor is generally used as a device for detecting a force applied by an operator by converting the intensity and direction of the force into electric signals. In particular, it is used as a two- or three-dimensional sensor capable of detecting each directional component of the applied force. For example, as an input device of a cellular phone, a capacitance type sensor for inputting a multidirectional operation is installed as a so-called joystick.

Into such a capacitance type sensor, an operation quantity having a predetermined dynamic range can be input as the intensity of a force applied by an operator. In a capacitance type sensor, a capacitive element is formed between two kinds of opposed electrodes of a capacitance electrode and a displacement electrode so as to detect a force on the basis of a change in the capacitance value of the capacitive element, for example, as disclosed in Japanese Patent Unexamined Publication No. 2003-35615.

In the capacitance type sensor, in order to detect a vertical force applied to a detective member, that is, a Z-axial force perpendicular to a substrate, one capacitance electrode E5 is formed on the substrate for detecting the Z-axial force component. The Z-axial force component is detected on the basis of a change in the capacitance value of the capacitive element formed between the capacitance electrode E5 and the displacement electrode when the detective member is Z-axially displaced.

When the detective member is depressed downward, that is, a Z-axial negative force is applied, the distance between the capacitance electrode E5 and the displacement electrode decreases to increase the capacitance value of the capacitive element. On the other hand, when the detective member is pulled upward, that is, a Z-axial positive force is applied, the distance between the capacitance electrode E5 and the displacement electrode increases to decrease the capacitance value of the capacitive element.

As shown in FIG. 14, the distance between the capacitance electrode E5 and the displacement electrode, and the capacitance value of the capacitive element formed between the electrodes, have an inversely proportional relation. Thus, even when the distance between the electrodes changes by the same value, the quantity of the change in the capacitance value when the distance between the electrodes increases, is smaller than the quantity of the change in the capacitance value when the distance between the electrodes decreases. This lowers the output sensitivity when the detective member is pulled upward, in comparison with the output sensitivity when the detective member is depressed downward. Thus, in the capacitance type sensor, there is generated a difference in sensitivity between a case in which a Z-axial positive force is applied to the detective member and a case in which a Z-axial negative force is applied to the detective member.

In addition, an operation of pulling the detective member upward is worse in operability than an operation of depressing the detective member downward. A touch sensor is known in which a number of pairs of optical fibers are disposed in an elastic member such as urethane foam.

### SUMMARY OF THE INVENTION

A principal object of the present invention is to provide a capacitance type sensor capable of detecting the displacement of a detective member with the same sensitivity regardless of the direction of a force applied to the detective member.

According to a first aspect of the present invention, a capacitance type sensor comprises a first substrate; a second substrate being distantly opposed to the first substrate; a detective member that receives an external force; a first capacitance electrode provided on an inside surface of the first substrate; a second capacitance electrode provided on an inside surface of the second substrate; and a first conductive member disposed between the first and second substrates and being kept at a ground or another fixed potential. The first conductive member cooperates with the first capacitance electrode to form a first capacitive element. The sensor further comprises a second conductive member disposed between the first and second substrates and being kept at the ground or another fixed potential. The second conductive member cooperates with the second capacitance electrode to form a second capacitive element. When the detective member is displaced perpendicularly to the first substrate, one of the distance between the first capacitance electrode and the first conductive member and the distance between the second capacitance electrode and the second conductive member increases while the other decreases. The displacement of the detective member can be recognized on the basis of detection of a change in the capacitance value of at least one of the first and second capacitive elements by using signals input to the first and second capacitance electrodes.

According to the above aspect, when the first and second conductive members are displaced by an external force received by the detective member, one of the distance between the first conductive member and the first capacitance electrode and the distance between the second conductive member and the second capacitance electrode increases while the other decreases. More specifically, when a force in a predetermined direction, perpendicular to the first substrate, is applied to the detective member, the distance between the first conductive member and the first capacitance electrode decreases. Thus, the displacement of the detective member can be detected on the basis of the quantity of the change in the capacitance value of the first capacitive element. When a force in the direction reverse to the predetermined direction is applied to the detective member, the distance between the second conductive member and the second capacitance electrode decreases. Thus, the displacement of the detective member can be detected on the basis of the quantity of the change in the capacitance value of the second capacitive element.

Therefore, regardless of the direction of the force applied to the detective member, the displacement of the detective member can be detected on the basis of the quantity of the change in the capacitance value when the distance between the electrodes constituting the capacitive element decreases. Thus, regardless of the direction of the force applied to the detective member, the displacement of the detective member can be detected with the same sensitivity.

In addition, the displacement of the detective member can be detected by using a differential principle using both the quantities of the changes in the capacitance values of the first and second capacitive elements. This more improves the sensitivity in detecting the displacement of the detective member.

Further, because either of the operations to the detective member in the predetermined and reverse directions can be performed by pushing the detective member, the operability is good in either direction.

According to a second aspect of the present invention, a capacitance type sensor comprises a first substrate; a second substrate being distantly opposed to the first substrate; a detective member that receives an external force; a first capacitance electrode provided on an inside surface of the first substrate; a second capacitance electrode provided on an inside surface of the second substrate; a first switch electrode provided on the inside surface of the first substrate and being kept at a ground or another fixed potential; a second switch electrode provided on the inside surface of the second substrate and being kept at the ground or another fixed potential; and a first conductive member disposed between the first and second substrates so as to be distant from the first switch electrode and kept in an insulated state. The first conductive member cooperates with the first capacitance electrode to form a first capacitive element. The sensor further comprises a second conductive member disposed between the first and second substrates so as to be distant from the second switch electrode and kept in an insulated state. The second conductive member cooperates with the second capacitance electrode to form a second capacitive element. When the detective member is displaced perpendicularly to the first substrate, one of the distance between the first capacitance electrode and the first conductive member and the distance between the second capacitance electrode and the second conductive member increases while the other decreases, and one of a state in which the first conductive member comes into contact with the first switch electrode and a state in which the second conductive member comes into contact with the second switch electrode can appear. The displacement of the detective member can be recognized on the basis of detection of a change in the capacitance value of at least one of the first and second capacitive elements by using signals input to the first and second capacitance electrodes.

According to the above aspect, when the first and second conductive members are displaced by an external force received by the detective member, one of the distance between the first conductive member and the first capacitance electrode and the distance between the second conductive member and the second capacitance electrode increases while the other decreases. More specifically, when a force in a predetermined direction, perpendicular to the first substrate, is applied to the detective member, the distance between the first conductive member and the first capacitance electrode decreases, and the first conductive member comes into contact with the first switch electrode. Thus, the displacement of the detective member can be detected on the basis of the quantity of the change in the capacitance value of the first capacitive element. When a force in the direction reverse to the predetermined direction is applied to the detective member, the distance between the second conductive member and the second capacitance electrode decreases, and the second conductive member comes into contact with the second switch electrode. Thus, the displacement of the detective member can be detected on the basis of the quantity of the change in the capacitance value of the second capacitive element.

Therefore, regardless of the direction of the force applied to the detective member, the displacement of the detective member can be detected on the basis of the quantity of the change in the capacitance value when the distance between the electrodes constituting the capacitive element decreases. Thus, regardless of the direction of the force applied to the detective member, the displacement of the detective member can be detected with the same sensitivity.

Further, because either of the operations to the detective member in the predetermined and reverse directions can be performed by pushing the detective member, the operability is good in either direction.

Further, when the first and second conductive member are not in contact with the respective first and second switch electrodes, the first and second conductive member are not electrically connected to any portion of the sensor so as to be kept in an insulated state. In this state, no voltages are applied to the first and second capacitive elements. Therefore, even if the positions of the first and second conductive members are somewhat shifted before and after an operation, substantially the same output signal corresponding to the first or second capacitive element of the capacitance type sensor can be obtained from the first or second capacitance electrode unless the first or second conductive member comes into contact with the first or second switch electrode. This reduces the hysteresis of the output signal corresponding to the first and second capacitive elements of the capacitance type sensor.

In the present invention, the first and second conductive members may be electrically connected to each other.

According to the above feature, in either of the case in which the first conductive member comes into contact with the first switch electrode and the case in which the second conductive member comes into contact with the second switch electrode, the displacement of the detective member can be detected by using a differential principle using both the quantities of the changes in the capacitance values of the first and second capacitive elements. This more improves the sensitivity in detecting the displacement of the detective member.

According to a third aspect of the present invention, a capacitance type sensor comprises a substrate; a detective member that receives an external force; a first capacitance electrode provided on one surface of the substrate; a second capacitance electrode provided on the other surface of the substrate; and a first conductive member disposed on the one surface side of the substrate and being kept at a ground or another fixed potential. The first conductive member cooperates with the first capacitance electrode to form a first capacitive element. The sensor further comprises a second conductive member disposed on the other surface side of the substrate and being kept at the ground or another fixed potential. The second conductive member cooperates with the second capacitance electrode to form a second capacitive element. When the detective member is displaced perpendicularly to the substrate, one of the distance between the first capacitance electrode and the first conductive member and the distance between the second capacitance electrode and the second conductive member increases while the other decreases. The displacement of the detective member can be recognized on the basis of detection of a change in the capacitance value of at least one of the first and second capacitive elements by using signals input to the first and second capacitance electrodes.

According to the above aspect, when the first and second conductive members are displaced by an external force received by the detective member, one of the distance between the first conductive member and the first capacitance electrode and the distance between the second conductive member and the second capacitance electrode increases while the other decreases. More specifically, when a force in a predetermined direction, perpendicular to the substrate, is applied to the detective member, the distance between the first conductive member and the first capacitance electrode decreases. Thus, the displacement of the detective member can be detected on the basis of the quantity of the change in the capacitance value of the first capacitive element. When a force in the direction reverse to the predetermined direction is applied to the detective member, the distance between the second conductive member and the second capacitance electrode decreases. Thus, the displacement of the detective member can be detected on the basis of the quantity of the change in the capacitance value of the second capacitive element.

Therefore, regardless of the direction of the force applied to the detective member, the displacement of the detective member can be detected on the basis of the quantity of the change in the capacitance value when the distance between the electrodes constituting the capacitive element decreases. Thus, regardless of the direction of the force applied to the detective member, the displacement of the detective member can be detected with the same sensitivity.

In addition, the displacement of the detective member can be detected by using a differential principle using both the quantities of the changes in the capacitance values of the first and second capacitive elements. This more improves the sensitivity in detecting the displacement of the detective member.

Further, because either of the operations to the detective member in the predetermined and reverse directions can be performed by pushing the detective member, the operability is good in either direction.

According to a fourth aspect of the present invention, a capacitance type sensor comprises a substrate; a detective member that receives an external force; a first capacitance electrode provided on one surface of the substrate; a second capacitance electrode provided on the other surface of the substrate; a first switch electrode provided on the one surface of the substrate and being kept at a ground or another fixed potential; a second switch electrode provided on the other surface of the substrate and being kept at the ground or another fixed potential; and a first conductive member disposed on the one surface side of the substrate so as to be distant from the first switch electrode and kept in an insulated state. The first conductive member cooperates with the first capacitance electrode to form a first capacitive element. The sensor further comprises a second conductive member disposed on the other surface side of the substrate so as to be distant from the second switch electrode and kept in an insulated state. The second conductive member cooperates with the second capacitance electrode to form a second capacitive element. When the detective member is displaced perpendicularly to the first substrate, one of the distance between the first capacitance electrode and the first conductive member and the distance between the second capacitance electrode and the second conductive member increases while the other decreases, and one of a state in which the first conductive member comes into contact with the first switch electrode and a state in which the second conductive member comes into contact with the second switch electrode can appear. The displacement of the detective member can be recognized on the basis of detection of a change in the capacitance value of at least one of the first and second capacitive elements by using signals input to the first and second capacitance electrodes.

According to the above aspect, when the first and second conductive members are displaced by an external force received by the detective member, one of the distance between the first conductive member and the first capacitance electrode and the distance between the second conductive member and the second capacitance electrode increases while the other decreases. More specifically, when a force in a predetermined direction, perpendicular to the substrate, is applied to the detective member, the distance between the first conductive member and the first capacitance electrode decreases, and the first conductive member comes into contact with the first switch electrode. Thus, the displacement of the detective member can be detected on the basis of the quantity of the change in the capacitance value of the first capacitive element. When a force in the direction reverse to the predetermined direction is applied to the detective member, the distance between the second conductive member and the second capacitance electrode decreases, and the second conductive member comes into contact with the second switch electrode. Thus, the displacement of the detective member can be detected on the basis of the quantity of the change in the capacitance value of the second capacitive element.

Therefore, regardless of the direction of the force applied to the detective member, the displacement of the detective member can be detected on the basis of the quantity of the change in the capacitance value when the distance between the electrodes constituting the capacitive element decreases. Thus, regardless of the direction of the force applied to the detective member, the displacement of the detective member can be detected with the same sensitivity.

Further, because either of the operations to the detective member in the predetermined and reverse directions can be performed by pushing the detective member, the operability is good in either direction.

Further, when the first and second conductive member are not in contact with the respective first and second switch electrodes, the first and second conductive member are not electrically connected to any portion of the sensor so as to be kept in an insulated state. In this state, no voltages are applied to the first and second capacitive elements. Therefore, even if the positions of the first and second conductive members are somewhat shifted before and after an operation, substantially the same output signal corresponding to the first or second capacitive element of the capacitance type sensor can be obtained from the first or second capacitance electrode unless the first or second conductive member comes into contact with the first or second switch electrode. This reduces the hysteresis of the output signal corresponding to the first and second capacitive elements of the capacitance type sensor.

In the present invention, the first and second conductive members may be electrically connected to each other.

According to the above feature, in either of the case in which the first conductive member comes into contact with the first switch electrode and the case in which the second conductive member comes into contact with the second switch electrode, the displacement of the detective member can be detected by using a differential principle using both the quantities of the changes in the capacitance values of the first and second capacitive elements. This more improves the sensitivity in detecting the displacement of the detective member.

### BRIEF DESCRIPTION OF THE DRAWINGS

Other and further objects, features and advantages of the invention will appear more fully from the following description taken in connection with the accompanying drawings in which:

FIG. 1 is a sectional view of a capacitance type sensor 10 according to a first embodiment of the present invention;

FIG. 2 shows the disposition of electrodes on a substrate 101 or 201 of the capacitance type sensor 10;

FIG. 3 is an equivalent circuit diagram corresponding to the construction of the capacitance type sensor 10 shown in FIG. 1;

FIG. 4 is for explaining a method of deriving an output signal from synchronous signals being input to the capacitance type sensor 10 shown in FIG. 1;

FIG. 5 is a sectional view of the capacitance type sensor 10 when a Z-axial positive force is applied to a detective member 105 of the capacitance type sensor 10 shown in FIG. 1;

FIG. 6 is a graph showing changes in the capacitance values of capacitive elements when the Z-axial positive force is applied;

FIG. 7 shows the disposition of electrodes on a substrate 121 or 221 of a capacitance type sensor according to a second embodiment of the present invention;

FIG. 8 is an equivalent circuit diagram corresponding to the construction of the capacitance type sensor of the second embodiment shown in FIG. 7;

FIG. 9 is a sectional view of a capacitance type sensor 30 according to a third embodiment of the present invention;

FIG. 10 is a sectional view of a capacitance type sensor 40 according to a fourth embodiment of the present invention;

FIG. 11 shows the disposition of electrodes on a lower or upper surface of a substrate 141 of the capacitance type sensor 40;

FIG. 12 is an equivalent circuit diagram corresponding to the construction of the capacitance type sensor 40 shown in FIG. 10;

FIG. 13 is for explaining a method of deriving an output signal from synchronous signals being input to the capacitance type sensor 40 shown in FIG. 10; and

FIG. 14 is a graph showing a change in the capacitance value of a capacitive element when a Z-axial force is applied.

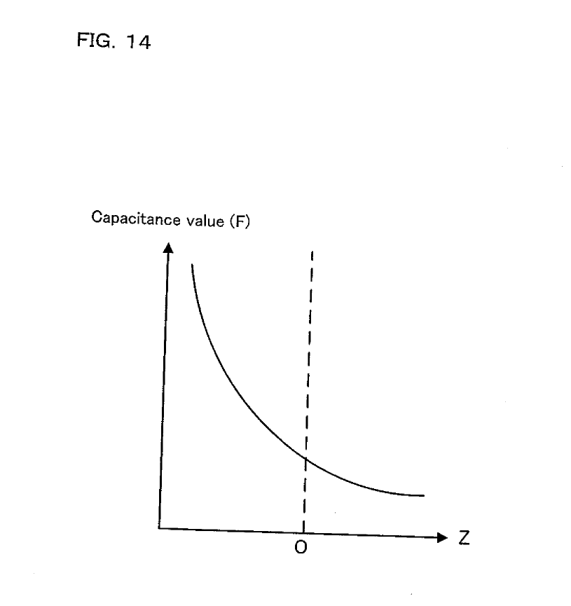

### DESCRIPTION OF THE PREFERRED EMBODIMENTS

Hereinafter, preferred embodiments of the present invention will be described with reference to the drawings.

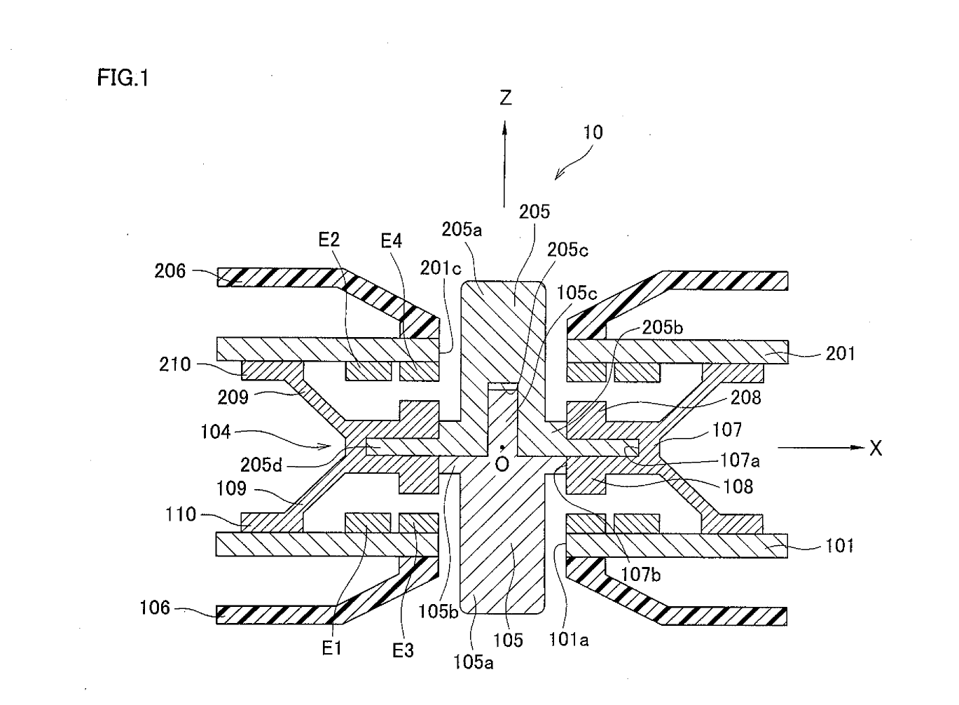

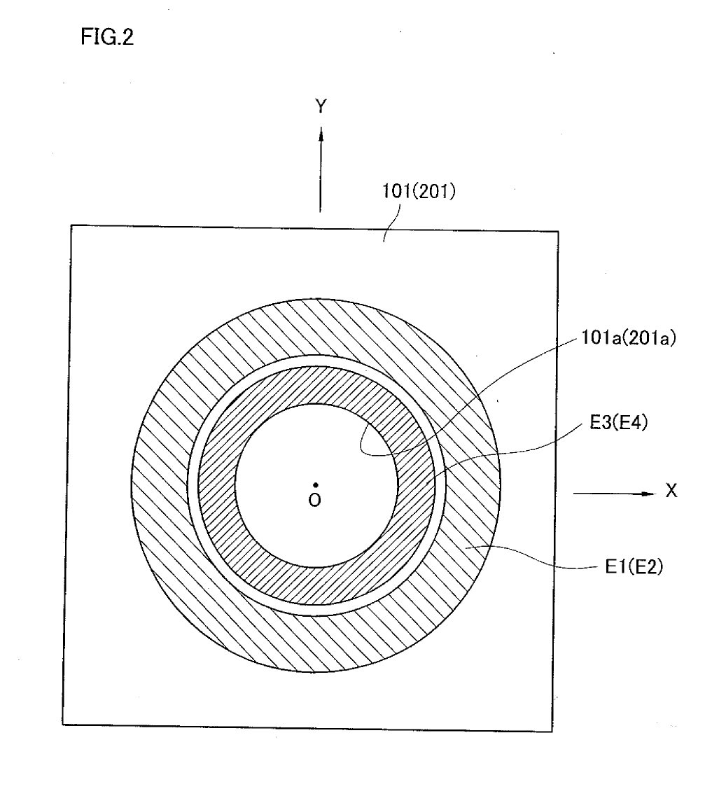

First, the construction of a capacitance type sensor 10 according to a first embodiment of the present invention will be described with reference to FIGS. 1 and 2.

FIG. 1 is a sectional view of the capacitance type sensor 10 according to the first embodiment of the present invention. FIG. 2 shows the disposition of electrodes on a substrate 101 or 201 of the capacitance type sensor 10.

As shown in FIG. 1, the capacitance type sensor 10 includes a substrate 101; a substrate 201 opposed to the substrate 101; a detective member 105 for detecting an external force; a detective member 205 for detecting an external force, in which the detective member 105 is fitted; a capacitance electrode E1 and a switch electrode E3 disposed on the upper surface of the substrate 101; a capacitance electrode E2 and a switch electrode E4 disposed on the lower surface of the substrate 201; a displacement electrode 104 supporting the detective members 105 and 205 between the substrates 101 and 201; and covers 106 and 206 covering the lower surface of the substrate 101 and the upper surface of the substrate 202, respectively.

For convenience of explanation, here is defined an XYZ three-dimensional coordinate system, and disposition of each component will be described with reference to the coordinate system. In FIG. 1, the origin O is defined at the center of the capacitance type sensor 10; the X axis is defined to extend horizontally rightward; the Z axis is defined to extend vertically upward; and the Y axis is defined to extend perpendicularly backward of FIG. 1.

The substrate 101 is disposed so as to be opposed to the substrate 201. Each of the substrates 101 and 201 is made of a general printed circuit board for an electronic circuit. In this embodiment, each of the substrates 101 and 201 is made of a glass epoxy board. A filmy substrate such as a polyimide film may be used for each of the substrates 101 and 201. In such a case, however, because the filmy substrate is flexible, it is preferably used in a state of being disposed on a sufficiently rigid supporting substrate.

As shown in FIGS. 1 and 2, holes 101a and 201a are formed in the respective substrate 101 and 201 around the Z axis. On the upper surface of the substrate 101 and the lower surface of the substrate 201, there are provided annular switch electrodes E3 and E4 disposed outside the respective holes 101a and 201a; and annular capacitance electrodes E1 and E2 disposed outside the respective switch electrodes E3 and E4. The capacitance and switch electrodes E1 and E3 are disposed so as to be opposed to the respective capacitance and switch electrodes E2 and E4.

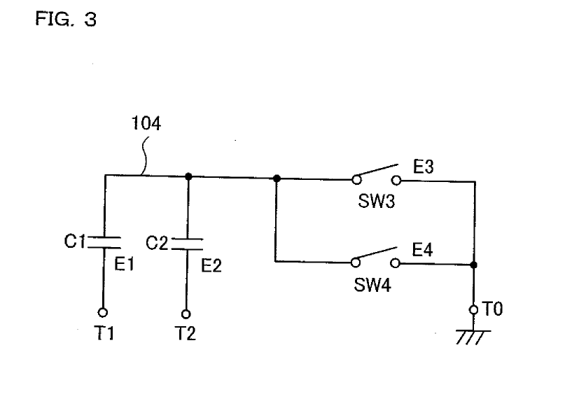

The capacitance electrodes E1 and E2 are annularly disposed around the Z axis to be used for detecting the Z-axial component of an external force. The capacitance electrodes E1 and E2 are connected to respective terminals T1 and T2, as shown in FIG. 3, by using through holes or the like. The capacitance electrodes E1 and E2 are connected to an external electronic circuit via the terminals T1 and T2.

In this embodiment, the surface of each of the capacitance electrodes E1 and E2 is covered with a not-shown insulating film as a resist film. Therefore, the capacitance electrodes E1 and E2 made of copper or the like are prevented from being exposed to air, and oxidation of them is thus prevented.

The switch electrodes E3 and E4 are annularly disposed around the Z axis to be used as detection switches for an external force. The switch electrodes E3 and E4 are connected to a terminal T0, as shown in FIG. 3, by using through holes or the like. The switch electrodes E3 and E4 are grounded via the terminal T0.

Referring back to FIG. 1, the displacement electrode 104 is made of an elastic, conductive material, for example, conductive Si rubber. The displacement electrode 104 is formed into an annular member having its outer shape smaller than the length of one side of the substrate 101. The displacement electrode 104 is made up of a large-diameter annular middle step portion 107; a small-diameter annular lower step portion 108 protruding downward from the middle step portion 107; a small-diameter annular upper step portion 208 protruding upward from the middle step portion 107; and large-diameter annular supporting portions 110 and 210 provided around the middle step portion 107. Thin portions 109 and 209 are provided near the outer periphery of the middle step portion 107. The thin portion 109 interconnects the middle step portion 107 and the supporting portion 110. The thin portion 209 interconnects the middle step portion 107 and the supporting portion 210. In the middle step portion 107, a circular hollow portion 107a is formed in which a lower step portion 205d of the detective member 205, which will be described later, is fitted. A hole 107b is formed around the Z axis through the upper, middle, and lower step portions 208, 107, and 108.

The supporting portion 110 is located at a level lower than the middle step portion 107. The lower surface of the supporting portion 110 is in contact with the upper surface of the substrate 101. The lower surface of the middle step portion 107 is at a predetermined distance from a surface of the substrate 101. Thus, a capacitive element C1 is formed between the lower surface of the middle step portion 107 of the displacement electrode 104 and the capacitance electrode E1. A gap of a predetermined distance is formed between the lower surface of the lower step portion 108 of the displacement electrode 104 and the switch electrode E3. The supporting portion 210 is located at a level higher than the middle step portion 107. The upper surface of the supporting portion 210 is in contact with the lower surface of the substrate 201. The upper surface of the middle step portion 107 is at a predetermined distance from a surface of the substrate 201. Thus, a capacitive element C2 is formed between the upper surface of the middle step portion 107 of the displacement electrode 104 and the capacitance electrode E2. A gap of a predetermined distance is formed between the upper surface of the upper step portion 208 of the displacement electrode 104 and the switch electrode E4.

The thin portions 109 and 209 make the upper, middle, and lower step portions 208, 107, and 108 of the displacement electrode 104 easy to be Z-axially displaced when a force is applied to the displacement electrode 104 via the detective member 105 or 205. The displacement electrode 104 has elasticity. Therefore, when the displacement electrode 104 is released from the applied force by which the thin portions 109 and 209 were elastically deformed so that the upper, middle, and lower step portions 208, 107, and 108 were Z-axially displaced, the upper, middle, and lower step portions 208, 107, and 108 automatically return to their original positions.

The detective member 105 is formed into a columnar member smaller in diameter than the hole 101a of the substrate 101. The detective member 105 is made up of a small-diameter lower step portion 105a to serve as a force receiving portion for a force from below; and an upper step portion 105b disposed on the upper end of the lower step portion 105a and having its diameter substantially equal to the diameter of the hole 107b. On the upper surface of the detective member 105, a small-diameter circular protrusion 105c is formed at the center of the upper surface of the detective member 105 so as to protrude upward.

The detective member 205 is formed into a columnar member having its diameter substantially equal to the diameter of the detective member 105. The detective member 205 is made up of a small-diameter upper step portion 205a to serve as a force receiving portion for a force from above; a middle step portion 205b disposed on the lower end of the upper step portion 205a and having its diameter substantially equal to the diameter of the hole 107b; and a large-diameter lower step portion 205d disposed on the lower end of the middle step portion 205b. At the lower end of the detective member 205, a small-diameter circular recess 205c open upward is formed at the center of the lower face of the detective member 205. The protrusion 105c of the detective member 105 is fitted in the recess 205c of the detective member 205. The lower step portion 205d of the detective member 205 is fitted in the hollow portion 107a of the middle step portion 107 of the displacement electrode 104. Thus, the detective members 105 and 205 and the displacement electrode 104 operate in an integrated manner.

The lower step portion 105a of the detective member 105 is somewhat smaller in diameter than the hole 101a of the substrate 101. The lower end of the lower step portion 105a protrudes downward beyond the hole 101a. The upper step portion 205a of the detective member 205 is somewhat smaller in diameter than the hole 201a of the substrate 201. The upper end of the upper step portion 205a protrudes upward beyond the hole 201a.

The cover 106 is bent inward over the periphery of the hole 101a of the substrate 101, and fixed to the lower surface of the substrate 101. Thereby, the cover 106 covers the lower surface of the substrate 101 with exposing the detective member 105 so that the detective member 105 is easy to be externally operated. The cover 206 is bent inward over the periphery of the hole 201a of the substrate 201, and fixed to the upper surface of the substrate 201. Thereby, the cover 206 covers the upper surface of the substrate 201 with exposing the detective member 205 so that the detective member 205 is easy to be externally operated.

Next, a circuit construction of the capacitance type sensor 10 of this embodiment will be described with reference to FIG. 3. FIG. 3 is an equivalent circuit diagram corresponding to the construction of the capacitance type sensor 10 shown in FIG. 1.

In the capacitance type sensor 10 of this embodiment, variable capacitive elements C1 and C2 whose capacitance values change in accordance with the displacement of the middle step portion 107 of the displacement electrode 104 are formed between the displaceable displacement electrode 104 as a common electrode shown in FIG. 1, particularly, its middle step portion 107, and the respective fixed individual capacitance electrodes E1 and E2. The distance between the middle step portion 107 and each of the capacitance electrodes E1 and E2 changes when a force is applied to the detective member 105 or 205. The distance returns to its original value when the detective member 105 or 205 is released from the applied force.

The switch electrodes E3 and E4 are grounded via the terminal T0. When no force is applied to the detective member 105 or 205, the displacement electrode 104 is not electrically connected to any portion of the capacitance type sensor 10 so as to be in an insulated state, that is, a separated state. Either of the switch electrodes E3 and E4 can take one of a state of being in contact with the displacement electrode 104 and a state of not being in contact with the displacement electrode 104. Thus, switches SW3 and SW4 are formed between the respective switch electrodes E3 and E4 and the displacement electrode 104.

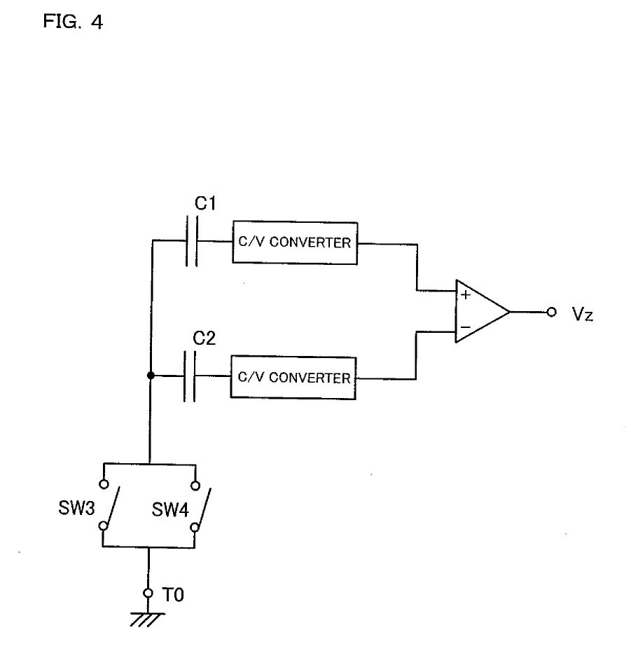

Next, a method of deriving an output signal that indicates the intensity and direction of an external force applied to the detective member 105 or 205, from a change in the capacitance value of each of the capacitive elements C1 and C2, will be described with reference to FIG. 4. FIG. 4 is for explaining the method of deriving the output signal from synchronous signals being input to the capacitance type sensor 10 shown in FIG. 1. Vz indicates the intensity and direction of the Z-axial component of an external force.

For deriving the output signal Vz, periodic signals such as clock signals are being input to the respective terminals T1 and T2. In this state, for example, when a Z-axial positive force is applied to the detective member 105, the displacement electrode 104 is pressed by the detective member 105 in the direction of the force so that the displacement electrode 104 is displaced. When the Z-axial positive force being applied to the detective member 105 reaches a predetermined value, the upper surface of the upper step portion 208 of the displacement electrode 104 comes into contact with the switch electrode E4.

When the displacement electrode 104 is further displaced after the displacement electrode 104 thus comes into contact with the switch electrode E4, each of the capacitive element C1 and C2 changes in its capacitance value so as to generate shifts in the phases of the periodic signals being input to the terminals T1 and T2. By using the shifts in the phases generated in the periodic signals, the output signal Vz can be obtained that indicates the Z-axial intensity and direction of the force externally applied to the detective member 105.

More specifically, when such periodic signals are being input to the respective terminals T1 and T2, a periodic signal A is being input to the terminal T1 while a periodic signal B is being input to the terminal T2. The periodic signal B has the same period as the periodic signal A but differs from the periodic signal A in phase. In this state, when a force is applied to the detective member 105 or 205 to change the capacitance value of each of the capacitive elements C1 and C2, shifts of different quantities are generated in the phase of the periodic signal A or the periodic signal B being input to the respective terminals T1 and T2.

That is, the capacitance value of the capacitive element C1 changes to generate a shift in the phase of the periodic signal A being input to the terminal T1, and the capacitance value of the capacitive element C2 changes to generate a shift in the phase of the periodic signal B being input to the terminal T2. The changes in the capacitance values of the capacitive elements C1 and C2 are in a relation in which one increases while the other decreases. Thus, the shift in the phase of the periodic signal A being input to the terminal T1 and the shift in the phase of the periodic signal B being input to the terminal T2 are in the directions reverse to each other. The output signal Vz is derived by reading the shifts in the phases of the periodic signals A and B being input to the respective terminals T1 and T2, by using a differential principle. The sign of the change in the output signal Vz indicates whether the Z-axial component of the external force is positive or negative; and the absolute value of the change in the output signal Vz indicates the intensity of the Z-axial component.

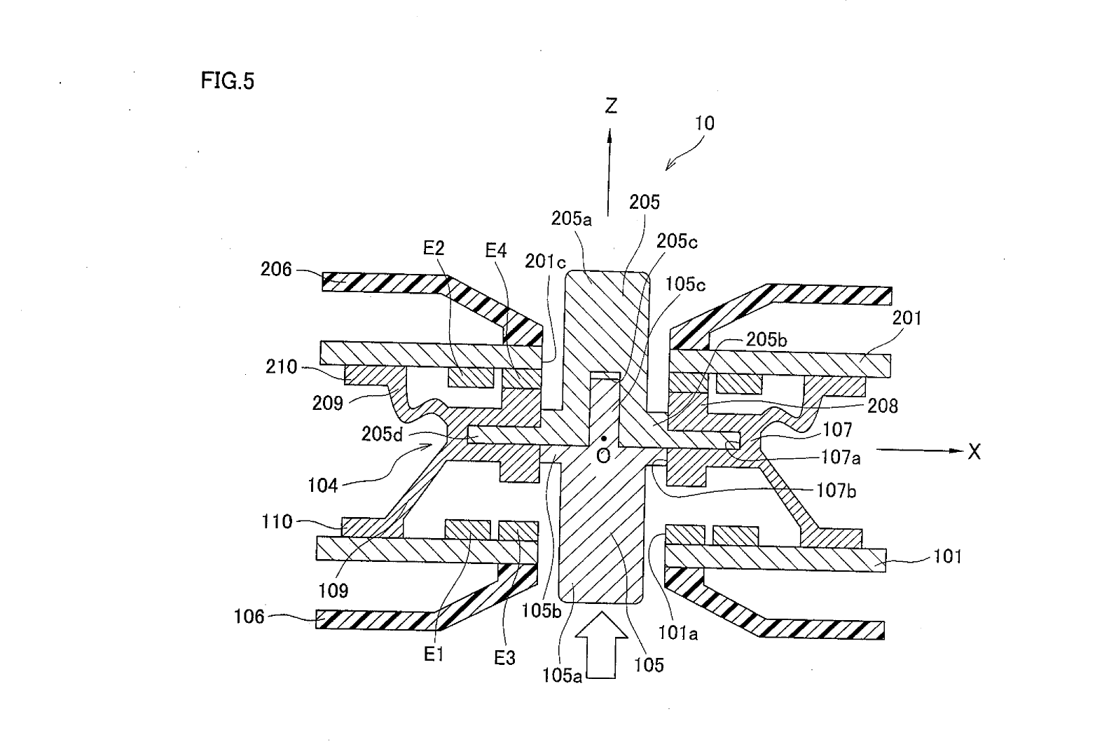

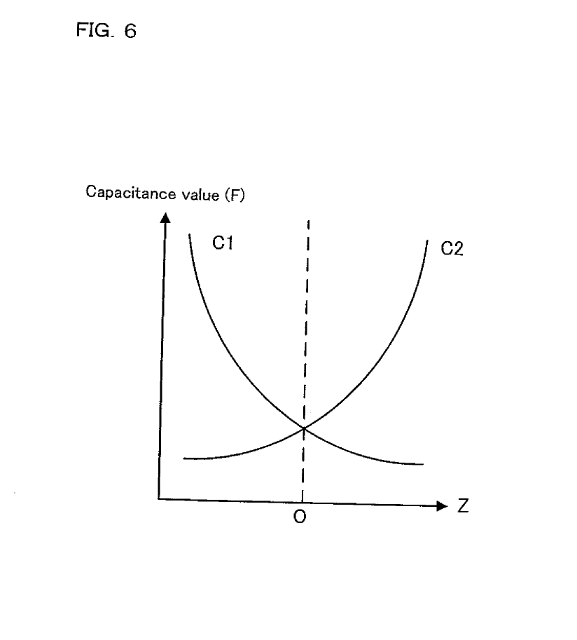

Next, an operation of the capacitance type sensor 10 will be described with reference to FIGS. 5 and 6. FIG. 5 is a sectional view of the capacitance type sensor 10 when a Z-axial positive force is applied to the detective member 105 of the capacitance type sensor 10 shown in FIG. 1. FIG. 6 is a graph showing changes in the capacitance values of the capacitive elements when the Z-axial positive force is applied.

First, as shown in FIG. 5, a Z-axial positive force is applied to the detective member 105. The detective member 105 is then displaced in the Z-axial positive direction. The middle step portion 107 of the displacement electrode 104 is then displaced with the detective member 105 in the Z-axial positive direction. Thus, a Z-axial positive force is applied to the displacement electrode 104.

By the above force, the middle step portion 107 of the displacement electrode 104 is displaced in the Z-axial positive direction. The displacement decreases the distance between the upper surface of the middle step portion 107 of the displacement electrode 104 and the capacitance electrode E2; and increases the lower surface of the middle step portion 107 of the displacement electrode 104 and the capacitance electrode E1. When the force becomes a predetermined intensity or more, the upper surface of the upper step portion 208 of the displacement electrode 104 being kept in an insulated state comes into contact with the grounded switch electrode E4. Thereby, the switch SW4 changes from its off-state into its on-state. Thus, the displacement electrode 104 is put at the ground potential.

In general, it is known that the capacitance value of a capacitive element is inversely proportional to the distance between the electrodes constituting the capacitive element. Thus, when the above-described operation turns the switch SW4 on; decreases the distance between the upper surface of the middle step portion 107 of the displacement electrode 104 and the capacitance electrode E2; and increases the lower surface of the middle step portion 107 of the displacement electrode 104 and the capacitance electrode E1, as shown in FIG. 6, this increases the capacitance value of the capacitive element C2 formed between the upper surface of the middle step portion 107 of the displacement electrode 104 and the capacitance electrode E2; and decreases the capacitance value of the capacitive element C1 formed between the lower surface of the middle step portion 107 of the displacement electrode 104 and the capacitance electrode E1. The output signal Vz is derived by using a differential principle on the capacitance values of the capacitive elements C1 and C2.

As described above, in the capacitance type sensor 10 of this embodiment, when the displacement electrode 104 is displaced by a force externally applied to the detective member 105 or 205, the distance between the displacement electrode 104 and the capacitance electrode E1 and the distance between the displacement electrode 104 and the capacitance electrode E2 are in a relation in which one increases while the other decreases. That is, when a Z-axial positive force is applied to the detective member 105, the displacement electrode 104 comes into contact with the switch electrode E4, and the displacement of the detective member 105 can be detected on the basis of the quantities of the changes in the capacitance values of the capacitive elements C1 and C2. When a Z-axial negative force is applied to the detective member 205, the displacement electrode 104 comes into contact with the switch electrode E3, and the displacement of the detective member 205 can be detected on the basis of the quantities of the changes in the capacitance values of the capacitive elements C1 and C2.

Thus, in either of the cases wherein the displacement electrode 104 comes into contact with the switch electrode E3 and wherein the displacement electrode 104 comes into contact with the switch electrode E4, the displacement of the detective member 105 or 205 can be detected by using a differential principle using both the quantities of the changes in the capacitance values of the capacitive elements C1 and C2. This improves the sensitivity in detecting the displacement of the detective member 105 or 205.

In addition, an operation for a Z-axial positive force can be performed by pressing the detective member 105, and an operation for a Z-axial negative force can be performed by pressing the detecting member 205. This improves the operability with respect to either of the Z-axial positive and negative directions.

Further, even if the position of the displacement electrode 104 is somewhat shifted before and after an operation, substantially the same output signal Vz corresponding to the capacitive elements C1 and C2 of the capacitance type sensor 10 can be obtained unless the displacement electrode 104 comes into contact with the switch electrode E3 or E4. This reduces the hysteresis of the output signal Vz corresponding to the capacitive elements C1 and C2 of the capacitance type sensor 10.

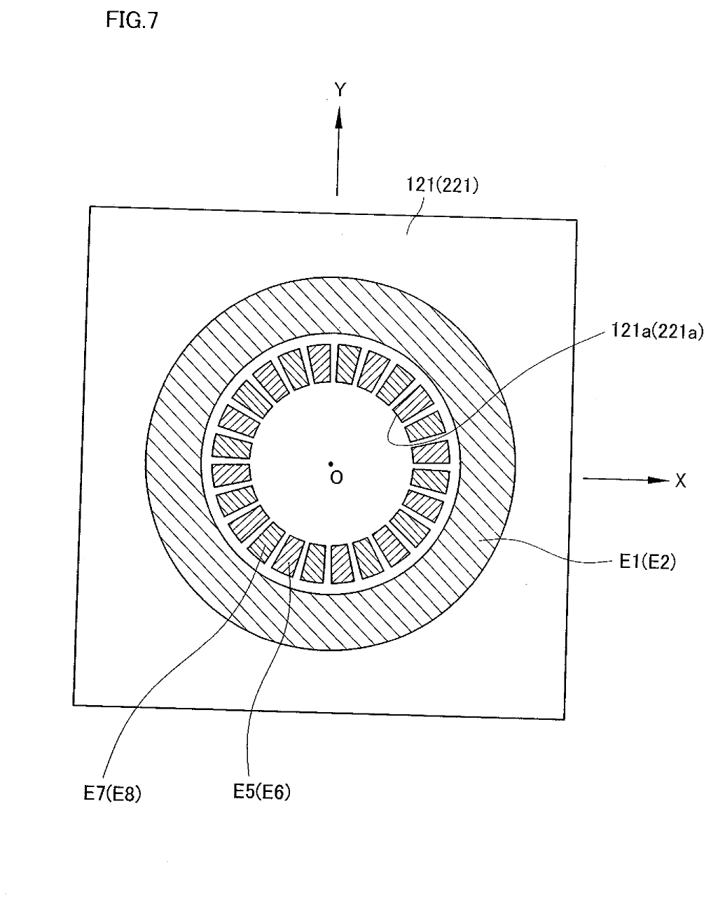

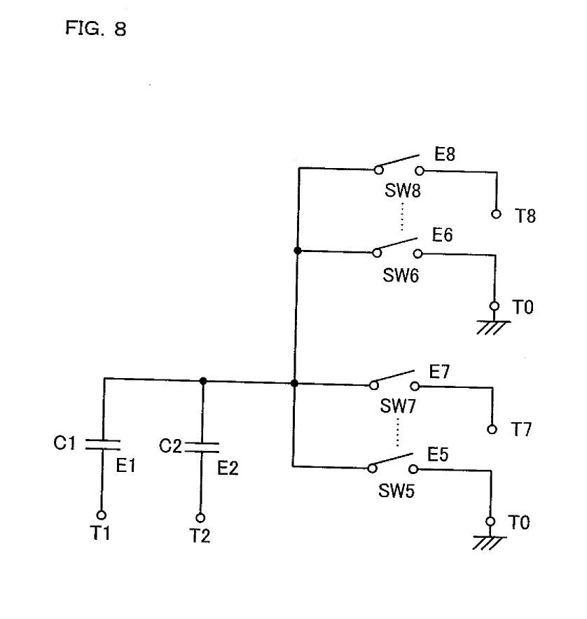

Next, the construction of a capacitance type sensor according to a second embodiment of the present invention will be described with reference to FIGS. 7 and 8. FIG. 7 shows the disposition of electrodes on a substrate 121 or 221 of the capacitance type sensor. FIG. 8 is an equivalent circuit diagram corresponding to the construction of the capacitance type sensor of the second embodiment shown in FIG. 7.

The capacitance type sensor of the second embodiment mainly differs in construction from the capacitance type sensor 10 of the first embodiment shown in FIG. 1 in a point that the switch electrodes E3 and E4 provided on the substrates 101 and 201 of the first embodiment are divided to form switch electrodes E5 and E6 and control electrodes E7 and E8. The other construction is substantially the same as the capacitance type sensor 10 of the first embodiment shown in FIG. 1, and therefore detailed description thereof will be omitted.

As shown in FIG. 7, holes 121a and 221a are formed in respective substrates 121 and 221 around the Z axis. On the upper surface of the substrate 121 and the lower surface of the substrate 221, a number of annular divided switch electrodes E5 and E6 and a number of annular divided control electrodes E7 and E8 are disposed around the holes 121a and 221a. Further, on the upper surface of the substrate 121 and the lower surface of the substrate 221, annular capacitance electrodes E1 and E2 are disposed around the switch electrodes E5 and E6 and control electrodes E7 and E8. The switch electrodes E5 and E6 and control electrodes E7 and E8 are divided from each other, and disposed alternately.

The divided switch electrodes E5 and E6 are annularly arranged around the Z axis to be used as detection switches for an external force. The divided switch electrodes E5 and E6 are connected to a terminal T0, as shown in FIG. 8, by using through holes or the like. The divided switch electrodes E5 and E6 are grounded via the terminal T0.

The divided control electrodes E7 and E8 are annularly arranged around the Z axis to be used as control switches for controlling when an external force is detected. The divided control electrodes E7 and E8 are connected to respective terminals T7 and T8, as shown in FIG. 8, by using through holes or the like.

Next will be described a circuit construction of the capacitance type sensor of this embodiment. As shown in FIG. 8, the switch electrodes E5 and E6 are grounded via the terminal T0. When no force is applied to the detective member 105 or 205, the displacement electrode 104 is not electrically connected to any portion of the capacitance type sensor 10 so as to be in an insulated state, that is, a separated state. Any of the switch electrodes E5 and E6 can take one of a state of being in contact with the displacement electrode 104 and a state of not being in contact with the displacement electrode 104. Thus, switches SW5 and SW6 are formed between the respective switch electrodes E5 and E6 and the displacement electrode 104.

As for the control electrodes E7 and E8, when no force is applied to the detective member 105 or 205, the displacement electrode 104 is not electrically connected to any portion of the capacitance type sensor so as to be in an insulated state, that is, a separated state. Any of the control electrodes E7 and E8 can take one of a state of being in contact with the displacement electrode 104 and a state of not being in contact with the displacement electrode 104. Thus, switches SW7 and SW8 are formed between the respective control electrodes E7 and E8 and the displacement electrode 104.

The manner of detecting an external force is the same as that of the first embodiment. When a Z-axial positive force is applied, the middle step portion 107 of the displacement electrode 104 is displaced in the Z-axial positive direction. When the force becomes a predetermined intensity or more, the upper surface of the upper step portion 208 of the displacement electrode 104 being kept in an insulated state, comes into contact with the grounded switch electrodes E6 and the control electrodes E8. Thereby, the switches SW6 and SW8 change from their off-state into their on-state. At this time, the switches SW8 change from their off-state into their on-state substantially simultaneously with the switches SW6.

A case in which a Z-axial negative force is applied is similar to the case in which the Z-axial positive force is applied, and therefore the description thereof is omitted here.

In the above construction, when the external force is detected and the switches SW7 or SW8 change from their off-state into their on-state, output signals can be taken through the terminals T7 or T8 to be used for various controls.

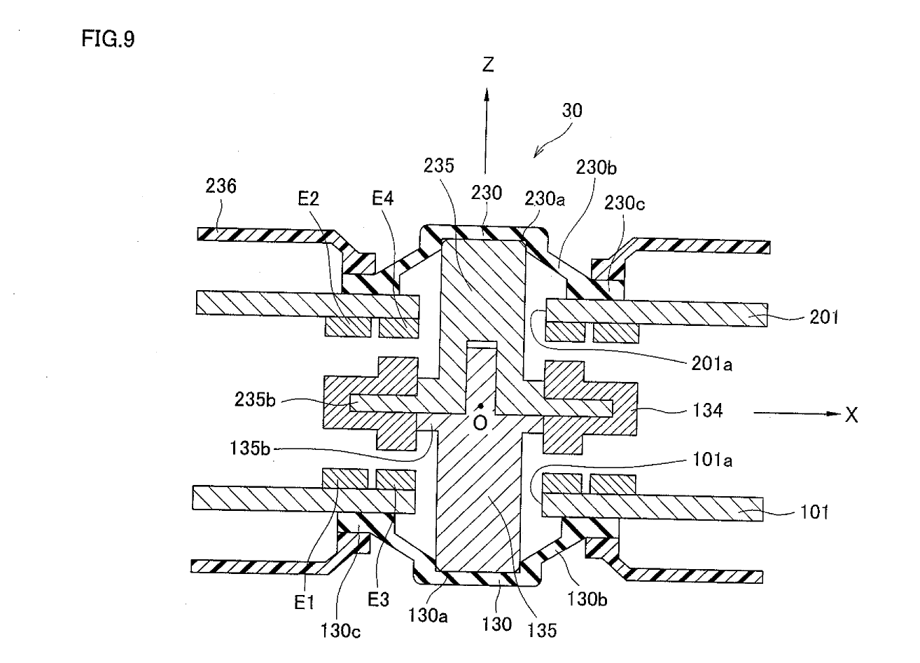

Next, the construction of a capacitance type sensor 30 according to a third embodiment of the present invention will be described with reference to FIG. 9. FIG. 9 is a sectional view of the capacitance type sensor 30 according to the third embodiment of the present invention, corresponding to the first embodiment shown in FIG. 1.

The capacitance type sensor 30 of this embodiment differs in construction from the capacitance type sensor 10 of the first embodiment in the following points. While an external force is directly applied to the detective member 105 or 205 in the first embodiment, caps 130 and 230 made of Si rubber are put on the respective detective members 105 and 205 in this embodiment so that an external force is indirectly applied to the detective member 105 or 205. In addition, a displacement electrode 134 is formed by providing the displacement electrode 104 with no thin portions 109 and 209 and no supporting portions 110 and 210. The other construction is substantially the same as the capacitance type sensor 10 of the first embodiment shown in FIG. 1, and therefore detailed description thereof will be omitted.

Each of the caps 130 and 230 is made of an elastic, insulating material, for example, insulating Si rubber. Each of the caps 130 and 230 is formed into an annular member having its outer shape smaller than the length of one side of the substrate 101. The caps 130 and 230 are made up of small-diameter cap portions 130a and 230a each having its diameter substantially equal to the diameter of the hole 101a of the substrate 101; and annular supporting portions 130c and 230c disposed around the respective cap portions 130a and 230a. Thin portions 130b and 230b are provided near the peripheries of the respective cap portions 130a and 230a. The thin portions 130b and 230b interconnect the cap portions 130a and 230a and the supporting portions 130c and 230c, respectively.

The thin portions 130b and 230b make a displacement electrode 134 easy to be Z-axially displaced when a force is applied to the displacement electrode 134 via detective member 135 or 235. When the displacement electrode 134 is released from the applied force by which the thin portions 130b and 230b were elastically deformed so that the displacement electrode 134 was Z-axially displaced, the displacement electrode 134 automatically returns to its original position.

The cap portions 130a and 230a cover the respective detective members 135 and 235. The supporting portion 130c is located at a higher level than the cap portion 130a. The upper surface of the supporting portion 130c is in contact with the lower surface of the substrate 101. The supporting portion 230c is located at a lower level than the cap portion 230a. The lower surface of the supporting portion 230c is in contact with the upper surface of the substrate 201. In addition, the supporting portions 130c and 230c of the caps 130 and 230 are pressed by covers 136 and 236, respectively.

In the above construction, because the caps 130 and 230 are made of Si rubber and pressed by the covers 136 and 236, they serve for packing. Thus, effects of waterproofing and dust-proofing can be obtained.

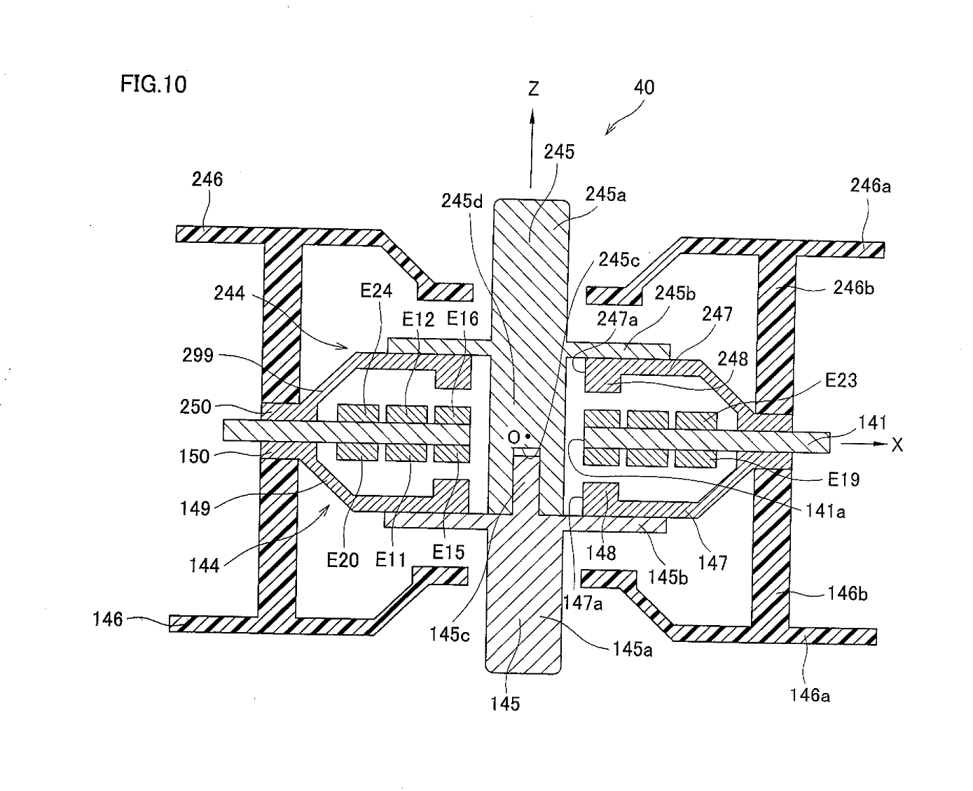

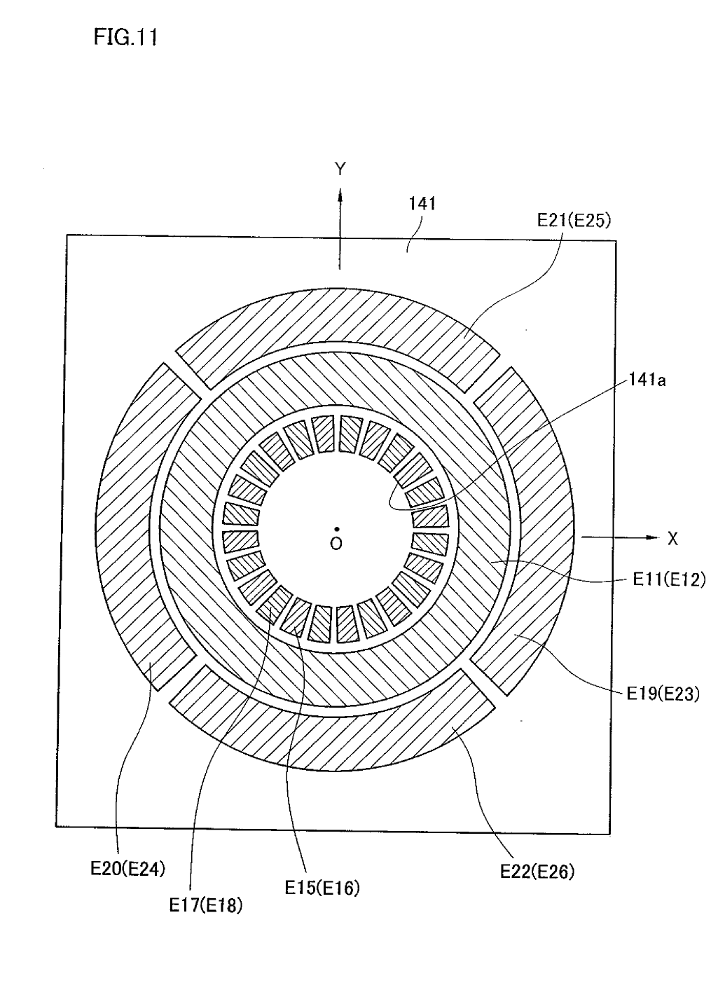

Next, the construction of a capacitance type sensor 40 according to a fourth embodiment of the present invention will be described with reference to FIGS. 10 to 13. FIG. 10 is a sectional view of the capacitance type sensor 40 according to the fourth embodiment of the present invention, corresponding to the first embodiment shown in FIG. 1. FIG. 11 shows the disposition of electrodes on the lower or upper surface of a substrate 141 of the capacitance type sensor 40.

As shown in FIG. 10, the capacitance type sensor 40 includes a substrate 141; a detective member 145 for detecting an external force; a detective member 245 for detecting an external force, in which the detective member is fitted; capacitance electrodes E11 and E19 to E22, switch electrodes E15, and control electrodes E17 disposed on the lower surface of the substrate 141, as shown in FIG. 11; capacitance electrodes E12 and E23 to E26, switch electrodes E16, and control electrodes E18 disposed on the upper surface of the substrate 141, as shown in FIG. 11; a displacement electrode 144 disposed under the substrate 141; a displacement electrode 244 disposed over the substrate 141; and covers 146 and 246 surrounding the above components.

For convenience of explanation, here is defined an XYZ three-dimensional coordinate system, and disposition of each component will be described with reference to the coordinate system. In FIG. 10, the origin O is defined at the center of the capacitance type sensor 40; the X axis is defined to extend horizontally rightward; the Z axis is defined to extend vertically upward; and the Y axis is defined to extend perpendicularly backward of FIG. 10.

As shown in FIG. 11, a hole 141a is formed in the substrate 141 around the Z axis. On the lower and upper surfaces of the substrate 141, switch electrodes E15 and E16 and control electrodes E17 and E18 are annularly disposed around the hole 141a. Further, on the lower and upper surfaces of the substrate 141, annular capacitance electrodes E11 and E12 are disposed outside the switch electrodes E15 and E16 and control electrodes E17 and E18. In addition, on the lower and upper surfaces of the substrate 141, substantially fan-shaped capacitance electrodes E19 to E22 and E23 to E26 are disposed outside the capacitance electrodes E11 and E12. The switch electrodes E15 and E16 and control electrodes E17 and E18 are divided from each other, and disposed alternately.

The capacitance electrodes E19 and E23 are disposed so as to correspond to the X-axial positive direction, and the capacitance electrodes E20 and E24 are disposed so as to correspond to the X-axial negative direction. They are used for detecting the X-axial component of an external force. The capacitance electrodes E21 and E25 are disposed so as to correspond to the Y-axial positive direction, and the capacitance electrodes E22 and E26 are disposed so as to correspond to the Y-axial negative direction. They are used for detecting the Y-axial component of the external force. The capacitance electrodes E11 and E12 are annularly disposed around the Z-axis to be used for the Z-axial component of the external force.

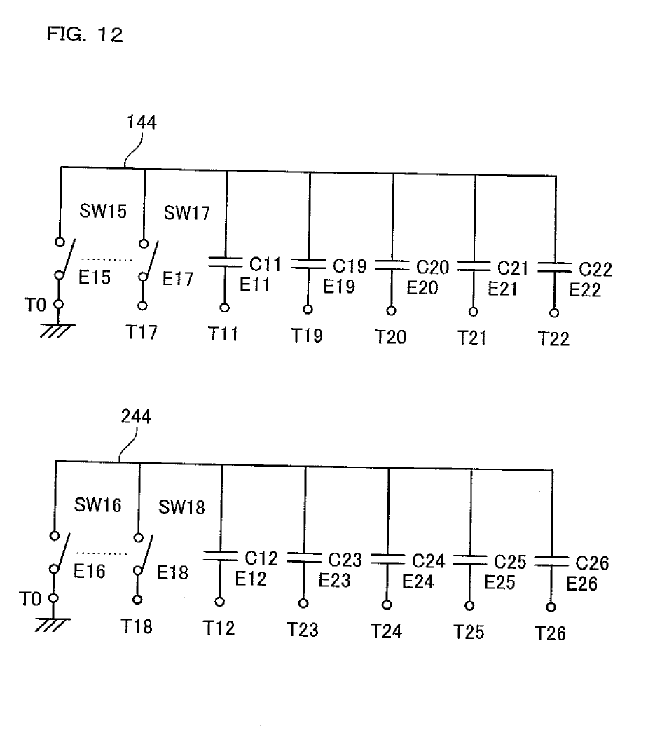

The capacitance electrodes E11, E12, and E19 to E26 are connected to respective terminals T11, T12, and T19 to T26, as shown in FIG. 12, by using through holes or the like. The capacitance electrodes E11, E12, and E19 to E26 are connected to an external electronic circuit via the terminals T11, T12, and T19 to T26.

In this embodiment, the surface of each of the capacitance electrodes E11, E12, and E19 to E26 is covered with a not-shown insulating film as a resist film. Therefore, the capacitance electrodes E11, E12, and E19 to E26 made of copper or the like are prevented from being exposed to air, and oxidation of them is thus prevented.

The divided switch electrodes E15 and E16 are annularly arranged around the Z axis to be used as detection switches for an external force. The divided switch electrodes E15 and E16 are connected to a terminal T0, as shown in FIG. 12, by using through holes or the like. The divided switch electrodes E15 and E16 are grounded via the terminal T0.

The divided control electrodes E17 and E18 are annularly arranged around the Z axis to be used as control switches for controlling when an external force is detected. The divided control electrodes E17 and E18 are connected to respective terminals T17 and T18, as shown in FIG. 12, by using through holes or the like.

Referring back to FIG. 10, the displacement electrode 144 is made of an elastic, conductive material, for example, conductive Si rubber. The displacement electrode 144 is formed into an annular member having its diameter shorter than one side of the substrate 141. The displacement electrode 144 is made up of a large-diameter annular lower step portion 147; a small-diameter annular upper step portion 148 protruding upward from the lower step portion 147; and a large-diameter annular supporting portion 150 provided around the lower step portion 147. A thin portion 149 is provided near the outer periphery of the lower step portion 147. The thin portion 149 interconnects the lower step portion 147 and the supporting portion 150. A hole 147a is formed around the Z axis through the lower and upper step portions 147 and 148.

The supporting portion 150 is located at a higher level than the lower step portion 147. The upper surface of the supporting portion 150 is in contact with the lower surface of the substrate 141. The upper surface of the lower step portion 147 is at a predetermined distance from the surface of the substrate 141. Thus, capacitive elements C11 and C19 to C22 are formed between the upper surface of the lower step portion 147 of the displacement electrode 144 and the capacitance electrodes E11 and E19 to 22, respectively. A gap of a predetermined distance is formed between the upper surface of the upper step portion 148 of the displacement electrode 144 and the switch electrodes E15 and control electrodes E17.

The displacement electrode 244 being opposed to the displacement electrode 144 through the substrate 141 is made of an elastic, conductive material, for example, conductive Si rubber. The displacement electrode 244 is formed into a disk-shaped member having its diameter shorter than one side of the substrate 141. The displacement electrode 244 is made up of a large-diameter annular upper step portion 247; a small-diameter annular lower step portion 248 protruding downward from the upper step portion 247; and a large-diameter annular supporting portion 250 provided around the upper step portion 247. A thin portion 249 is provided near the outer periphery of the upper step portion 247. The thin portion 249 interconnects the upper step portion 247 and the supporting portion 250. A hole 247a is formed around the Z axis through the upper and lower step portions 247 and 248.

The supporting portion 250 is located at a lower level than the upper step portion 247. The lower surface of the supporting portion 250 is in contact with the upper surface of the substrate 141. The lower surface of the upper step portion 247 is at a predetermined distance from the surface of the substrate 141. Thus, capacitive elements C12 and C23 to C26 are formed between the lower surface of the upper step portion 247 of the displacement electrode 244 and the capacitance electrodes E12 and E23 to 26, respectively. A gap of a predetermined distance is formed between the upper surface of the lower step portion 248 of the displacement electrode 244 and the switch electrodes E16 and control electrodes E18.

The thin portions 149 and 249 make the lower and upper step portions 147 and 148 of the displacement electrode 144 and the upper and lower step portions 247 and 248 of the displacement electrode 244 easy to be Z-axially displaced when a force is applied to the displacement electrodes 144 and 244 via the detective member 145 or 245. The displacement electrodes 144 and 244 have elasticity. Therefore, when the displacement electrodes 144 and 244 are released from the applied force by which the thin portions 149 and 249 were elastically deformed so that the lower and upper step portions 147 and 148 of the displacement electrode 144 and the upper and lower step portions 247 and 248 of the displacement electrode 244 were Z-axially displaced, the lower and upper step portions 147 and 148 of the displacement electrode 144 and the upper and lower step portions 247 and 248 of the displacement electrode 244 automatically return to their original positions.

The detective member 145 is formed into a columnar member smaller in diameter than the hole 141a of the substrate 141. The detective member 145 is made up of a small-diameter lower step portion 145a to serve as a force receiving portion for a force from below; and a large-diameter upper step portion 145b disposed on the upper end of the lower step portion 145a. On the upper surface of the detective member 145, a small-diameter circular protrusion 145c is formed at the center of the upper surface of the detective member 145 so as to protrude upward. The lower surface of the lower step portion 147 of the displacement electrode 144 is in contact with the upper surface of the upper step portion 145b.

The detective member 245 is formed into a columnar member having its diameter substantially equal to the diameter of the detective member 145. The detective member 245 is made up of a small-diameter upper step portion 245a to serve as a force receiving portion for a force from above; a large-diameter middle step portion 245b disposed in the middle of the upper step portion 245a; and a lower step portion 245d having its diameter substantially equal to the diameter of the upper step portion 245a. At the lower end of the detective member 245, a small-diameter circular recess 245c open upward is formed at the center of the lower face of the detective member 245. The upper surface of the upper step portion 247 of the displacement electrode 244 is in contact with the lower surface of the middle step portion 245b. The lower step portion 245d extends through the hole 141a of the substrate 141. The protrusion 145c of the detective member 145 is fitted in the recess 245c of the detective member 245. Thus, the detective members 145 and 245 and the displacement electrodes 144 and 244 operate in an integrated manner.

The cover 146 includes a cover portion 146a. The cover portion 146a is bent inward over the whole periphery of the lower step portion 145a of the detective member 145. The cover portion 146a has an opening larger than the diameter of the lower step portion 145a. The lower end of the lower step portion 145a protrudes downward through the opening. A cylindrical supporting portion 146b is formed on the upper surface of the cover portion 146a so as to be in contact with the supporting portion 150 of the displacement electrode 144. In this structure, the cover 146 covers the lower surface of the substrate 141 with exposing the detective member 145 so that the detective member 145 is easy to be externally operated.

The cover 246 includes a cover portion 246a. The cover portion 246a is bent inward over the whole periphery of the upper step portion 245a of the detective member 245. The cover portion 246a has an opening larger than the diameter of the upper step portion 245a. The upper end of the upper step portion 245a protrudes upward through the opening. A cylindrical supporting portion 246b is formed on the upper surface of the cover portion 246a so as to be in contact with the supporting portion 250 of the displacement electrode 244. In this structure, the cover 246 covers the upper surface of the substrate 141 with exposing the detective member 245 so that the detective member 245 is easy to be externally operated.

The supporting portion 150 of the displacement electrode 144 and the supporting portion 250 of the displacement electrode 244 are fixed to the substrate 141 by the supporting portion 146b of the cover 146 and the supporting portion 246b of the cover 246.

Next, a circuit construction of the capacitance type sensor 40 of this embodiment will be described with reference to FIG. 12. FIG. 12 is an equivalent circuit diagram corresponding to the construction of the capacitance type sensor 40 shown in FIG. 10.

In the capacitance type sensor 40 of this embodiment, variable capacitive elements C11 and C19 to C22 whose capacitance values change in accordance with the displacement of the lower step portion 147 of the displacement electrode 144 are formed between the displaceable displacement electrode 144 as a common electrode shown in FIG. 10, particularly, its lower step portion 147, and the respective fixed individual capacitance electrodes E11 and E19 to E22. The distance between the lower step portion 147 and each of the capacitance electrodes E11 and E19 to E22 changes when a force is applied to the detective member 145 or 245. The distance returns to its original value when the detective member 145 or 245 is released from the applied force.

Variable capacitive elements C12 and C23 to C26 whose capacitance values change in accordance with the displacement of the upper step portion 247 of the displacement electrode 244 are formed between the displaceable displacement electrode 244 as a common electrode shown in FIG. 10, particularly, its upper step portion 247, and the respective fixed individual capacitance electrodes E12 and E23 to E26. The distance between the upper step portion 247 and each of the capacitance electrodes E12 and E23 to E26 changes when a force is applied to the detective member 145 or 245. The distance returns to its original value when the detective member 145 or 245 is released from the applied force.

The switch electrodes E15 and E16 are grounded via the terminal T0. When no force is applied to the detective member 145 or 245, either of the displacement electrodes 144 and 244 is not electrically connected to any portion of the capacitance type sensor 40 so as to be in an insulated state, that is, a separated state. The switch electrode E15 can take one of a state of being in contact with the displacement electrode 144 and a state of not being in contact with the displacement electrode 144. Thus, a switch SW15 is formed between the switch electrode E15 and the displacement electrode 144. The switch electrode E16 can take one of a state of being in contact with the displacement electrode 245 and a state of not being in contact with the displacement electrode 245. Thus, a switch SW16 is formed between the switch electrode E16 and the displacement electrode 244.

As for the control electrodes E17 and E18, when no force is applied to the detective member 145 or 245, either of the displacement electrodes 144 and 244 is not electrically connected to any portion of the capacitance type sensor 40 so as to be in an insulated state, that is, a separated state. The control electrode E17 can take one of a state of being in contact with the displacement electrode 144 and a state of not being in contact with the displacement electrode 144. Thus, a switch SW17 is formed between the control electrode E17 and the displacement electrode 144. The control electrode E18 can take one of a state of being in contact with the displacement electrode 245 and a state of not being in contact with the displacement electrode 245. Thus, a switch SW18 is formed between the control electrode E18 and the displacement electrode 244.

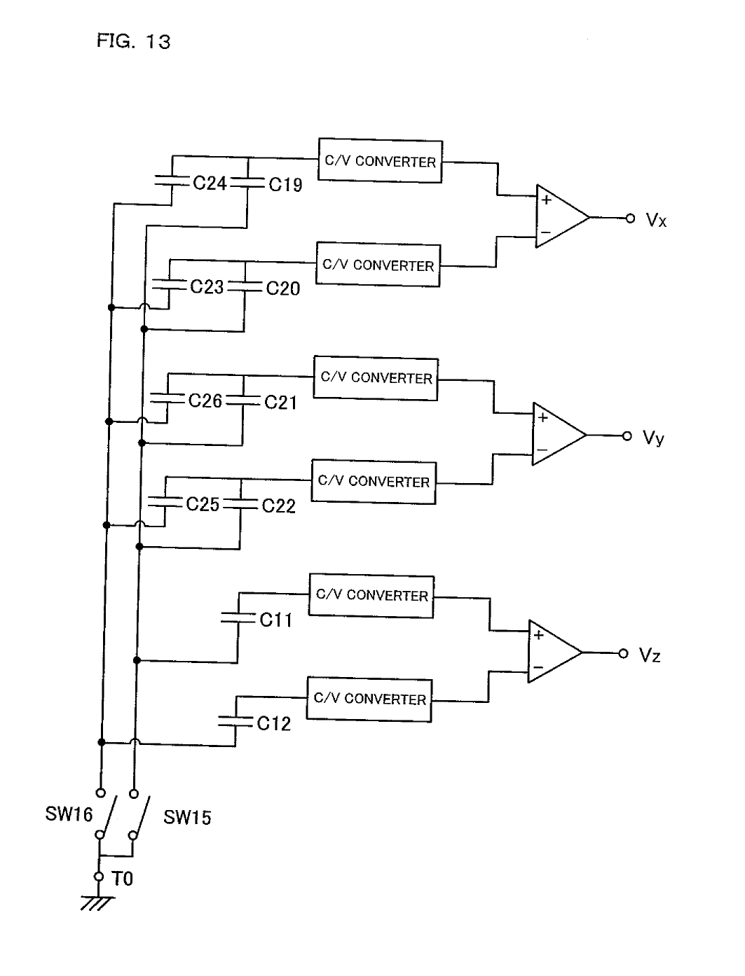

Next, a method of deriving output signals that indicate the intensity and direction of an external force applied to the detective member 145 or 245, from a change in the capacitance value of each of the capacitive elements C11, C12, and C19 to C26, will be described with reference to FIG. 13. Vx, Vy, and Vz indicate the intensities and directions of the X-, Y-, and Z-axial components of an external force, respectively.

The capacitive elements 19 and 24; 20 and 23; 21 and 26; and 22 and 25 are connected in parallel.

For deriving the output signals Vx, Vy, and Vz, periodic signals such as clock signals are being input to the respective terminals T11, T12, and T19 to T26. In this state, for example, when an X-axial positive force and a Z-axial positive force are applied to the detective member 145, the lower step portion 147 of the displacement electrode 144 is pressed by the detective member 145 in the direction of the forces so that the lower step portion 147 of the displacement electrode 144 is inclined. At this time, a portion of the lower step portion 147 of the displacement electrode 144 downstream in the force direction is displaced upward while a portion of the lower step portion 147 of the displacement electrode 144 upstream in the force direction is displaced upward. When a horizontal force being applied to the detective member 145 reaches a predetermined value, the portion of the lower step portion 147 of the displacement electrode 144 downstream in the force direction comes into contact with the switch electrode E15.

When the displacement electrode 144 is further inclined after the displacement electrode 144 thus comes into contact with the switch electrode E15, each of the capacitive element C11 and C19 to C22 changes in its capacitance value so as to generate shifts in the phases of the periodic signals being input to the terminals T11 and T19 to T22. By using the shifts in the phases generated in the periodic signals, the output signals Vx, Vy, and Vz can be obtained that indicate the respective X-, Y-, and Z-axial intensities and directions of the force externally applied to the detective member 145.

In accordance with the manner of applying the X- and Z-axial positive forces to the detective member 145, when a horizontal force is further applied to the detective member 145 simultaneously with or after the contact of the lower step portion 147 of the displacement electrode 144 with the switch electrode E15, the upper step portion 247 of the displacement electrode 244 comes into contact with the switch electrode E16.

In the above case, when the displacement electrode 144 is further inclined after the displacement electrode 144 comes into contact with the switch electrode E15, each of the capacitive element C11 and C19 to C22 changes in its capacitance value so as to generate shifts in the phases of the periodic signals being input to the terminals T11 and T19 to T22. In addition, when the displacement electrode 244 is further inclined after the displacement electrode 244 comes into contact with the switch electrode E16, each of the capacitive element C12 and C23 to C26 changes in its capacitance value so as to generate shifts in the phases of the periodic signals being input to the terminals T12 and T23 to T26. By using the shifts in the phases generated in the periodic signals, the output signals Vx, Vy, and Vz can be obtained that indicate the respective X-, Y-, and Z-axial intensities and directions of the force externally applied to the detective member 145.

The operation when an X-axial positive force and a Z-axial negative force are applied to the detective member 245 is similar to the operation when the X-axial positive force and the Z-axial positive force are applied to the detective member 145. Thus, the description thereof is omitted here.

More specifically, when such periodic signals are being input to the respective terminals T11, T12, and T19 to T26, periodic signals A in the same phase are being input to the terminals T11, T19, T21, T24, and T26 while periodic signals B are being input to the terminals T12, T20, T22, T23, and T25. The periodic signals B have the same period as the periodic signals A but differ from the periodic signals A in phase. In this state, when a force is applied to the detective member 145 or 245 to change the capacitance value of each of the capacitive elements C11, C12, and C19 to C26, shifts of different quantities are generated in the phases of the periodic signals A or the periodic signals B being input to the terminals T11, T12, and T19 to T26.

That is, when the external force has its X-axial component and the switch 15 is turned on, the capacitance value of the capacitive element C19 changes to generate a shift in the phase of the periodic signal A being input to the terminal T19, and the capacitance value of the capacitive element C20 changes to generate a shift in the phase of the periodic signal B being input to the terminal T20. The changes in the capacitance values of the capacitive elements C19 and C20 correspond to the X-axial positive and negative components of the external force, respectively. Thus, the shift in the phase of the periodic signal A being input to the terminal T19 and the shift in the phase of the periodic signal B being input to the terminal T20 are in the directions reverse to each other. The output signal Vx is derived by reading the shifts in the phases of the periodic signals A and B being input to the respective terminals T19 and T20, by using an exclusive-OR circuit or the like. The sign of the change in the output signal Vx indicates whether the X-axial component of the external force is positive or negative; and the absolute value of the change in the output signal Vx indicates the intensity of the X-axial component. A case in which the switch 16 is turned on is similar to the case in which the switch 15 is turned on. A case in which the external force has its Y- and Z-axial components is similar to the case in which the external force has its X-axial component.

As described above, in the capacitance type sensor 40 of this embodiment, when the displacement electrodes 144 and 244 are displaced by a force externally applied to the detective member 145 or 245, the distance between the displacement electrode 144 and the capacitance electrode E11 and the distance between the displacement electrode 244 and the capacitance electrode E12 are in a relation in which one increases while the other decreases. That is, when a Z-axial positive force is applied to the detective member 145, the distance between the displacement electrode 144 and the capacitance electrode E11 decreases so that the displacement electrode 144 comes into contact with the switch electrode E15. Thus, the displacement of the detective member 145 can be detected on the basis of the quantity of the change in the capacitance value of the capacitive element C11. When a Z-axial negative force is applied to the detective member 245, the distance between the displacement electrode 244 and the capacitance electrode E12 decreases so that the displacement electrode 244 comes into contact with the switch electrode E16. Thus, the displacement of the detective member 245 can be detected on the basis of the quantity of the change in the capacitance value of the capacitive element C12.

Thus, regardless of whether the Z-axial force is positive or negative, the displacement of the detective member 145 or 245 can be detected on the basis of the quantity of the change in capacitance value when the distance between the electrodes constituting the corresponding capacitive element decreases. Therefore, regardless of whether the Z-axial force is positive or negative, the displacement of the detective member 145 or 245 can be detected with the same sensitivity.

In addition, an operation for a Z-axial positive force can be performed by pressing the detective member 145, and an operation for a Z-axial negative force can be performed by pressing the detecting member 245. This improves the operability with respect to either of the Z-axial positive and negative directions.

Further, even if the position of the displacement electrode 144 or 244 is somewhat shifted before and after an operation, substantially the same output signals corresponding to the capacitive elements C11, C12, and C19 to C26 of the capacitance type sensor 40 can be obtained unless the displacement electrode 144 comes into contact with the switch electrode E15 or the displacement electrode 244 comes into contact with the switch electrode E16. This reduces the hysteresis of each of the output signals Vx, Vy, and Vz corresponding to the capacitive elements C11, C12, and C19 to C26 of the capacitance type sensor.

For example, in the above-described first embodiment, the member that cooperates with the capacitance electrode E1 to form the capacitive element C1, is electrically connected to the member that cooperates with the capacitance electrode E2 to form the capacitive element C2. In a modification, however, the member that cooperates with the capacitance electrode E1 to form the capacitive element C1, and the member that cooperates with the capacitance electrode E2 to form the capacitive element C2, may be separately provided and may not be electrically connected to each other. In the modification, regardless of the direction of a force applied to the detective member 105 or 205, by detecting the displacement of the detective member on the basis of the quantity of the change in capacitance value when the distance between the electrodes constituting the corresponding capacitive element decreases, the displacement of the detective member can be detected with the same sensitivity regardless of the direction of the force applied to the detective member 105 or 205.

In the above-described first embodiment, the displacement electrode 104 is not electrically connected to any portion of the capacitance type sensor so as to be in an insulated states that is, a separated state. In a modification, however, the displacement electrode 104 may not be electrically insulated. Also, in the above-described fourth embodiment, the displacement electrodes 144 and 244 are not electrically connected to any portion of the capacitance type sensor so as to be in an insulated state, that is, a separated state. In a modification, however, the displacement electrodes 144 and 244 may not be electrically insulated.

In the above-described first embodiment, only the capacitance electrodes E1 and E2 for detecting a Z-axial force are provided so that only the Z-axial force can be detected. In a modification, however, like the above-described fourth embodiment, capacitance electrodes for detecting X- and Y-axial forces may be provided so that X-, Y-, and Z-axial forces can be detected.

In the above-described fourth embodiment, the capacitance electrodes E11, E12, and E19 to E26 for detecting X-, Y-, and Z-axial forces are provided so that the X-, Y-, and Z-axial forces can be detected. In a modification, however, only capacitance electrodes for detecting a Z-axial force may be provided so that only the Z-axial force can be detected.

In the above-described fourth embodiment, the capacitance electrodes E19 to E26 for detecting X- and Y-axial forces are disposed outside the capacitance electrodes E11 and E12 for detecting a Z-axial force. In a modification, however, capacitance electrodes for detecting X- and Y-axial forces may be disposed inside, and capacitance electrodes for detecting a Z-axial force may be disposed outside the capacitance electrodes for detecting the X- and Y-axial forces.

In the above-described fourth embodiment, the displacement electrodes 144 and 244 are separated and electrically insulated from each other. In a modification, however, the displacement electrodes 144 and 244 may not be separated but made into one body, and they may be electrically connected to each other. In the modification, in either of the case in which the displacement electrode comes into contact with the switch electrode E15 and the case in which the displacement electrode comes into contact with the switch electrode E16, the displacement of the detective member 145 or 245 can be detected by using a differential principle using both the quantities of the changes in the capacitance values of the capacitive elements C11 and C12. This improves the sensitivity in detecting the displacement of the detective member.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. A capacitance type sensor comprising:
a first substrate;
a second substrate being distantly opposed to the first substrate;
a detective member that receives an external force;
a first capacitance electrode provided on an inside surface of the first substrate;
a second capacitance electrode provided on an inside surface of the second substrate;
a first conductive member disposed between the first and second substrates and being kept at a ground or another fixed potential, the first conductive member cooperating with the first capacitance electrode to form a first capacitive element; and
a second conductive member disposed between the first and second substrates and being kept at the ground or another fixed potential, the second conductive member cooperating with the second capacitance electrode to form a second capacitive element,
one of the distance between the first capacitance electrode and the first conductive member and the distance between the second capacitance electrode and the second conductive member increasing while the other decreases when the detective member is displaced perpendicularly to the first substrate,
the displacement of the detective member being able to be recognized on the basis of detection of a change in the capacitance value of at least one of the first and second capacitive elements by using signals input to the first and second capacitance electrodes.

2. A capacitance type sensor comprising:
a first substrate;
a second substrate being distantly opposed to the first substrate;
a detective member that receives an external force;
a first capacitance electrode provided on an inside surface of the first substrate;
a second capacitance electrode provided on an inside surface of the second substrate;
a first switch electrode provided on the inside surface of the first substrate and being kept at a ground or another fixed potential;
a second switch electrode provided on the inside surface of the second substrate and being kept at the ground or another fixed potential;
a first conductive member disposed between the first and second substrates so as to be distant from the first switch electrode and kept in an insulated state, the first conductive member cooperating with the first capacitance electrode to form a first capacitive element; and
a second conductive member disposed between the first and second substrates so as to be distant from the second switch electrode and kept in an insulated state, the second conductive member cooperating with the second capacitance electrode to form a second capacitive element,
one of the distance between the first capacitance electrode and the first conductive member and the distance between the second capacitance electrode and the second conductive member increasing while the other decreases, and one of a state in which the first conductive member comes into contact with the first switch electrode and a state in which the second conductive member comes into contact with the second switch electrode being able to appear, when the detective member is displaced perpendicularly to the first substrate,
the displacement of the detective member being able to be recognized on the basis of detection of a change in the capacitance value of at least one of the first and second capacitive elements by using signals input to the first and second capacitance electrodes.

3. The capacitance type sensor according to claim 2, wherein the first and second conductive members are electrically connected to each other.

4. A capacitance type sensor comprising:
a substrate;
a detective member that receives an external force;
a first capacitance electrode provided on one surface of the substrate;
a second capacitance electrode provided on the other surface of the substrate;
a first conductive member disposed on the one surface side of the substrate and being kept at a ground or another fixed potential, the first conductive member cooperating with the first capacitance electrode to form a first capacitive element; and
a second conductive member disposed on the other surface side of the substrate and being kept at the ground or another fixed potential, the second conductive member cooperating with the second capacitance electrode to form a second capacitive element,
one of the distance between the first capacitance electrode and the first conductive member and the distance between the second capacitance electrode and the second conductive member increasing while the other decreases when the detective member is displaced perpendicularly to the substrate,
the displacement of the detective member being able to be recognized on the basis of detection of a change in the capacitance value of at least one of the first and second capacitive elements by using signals input to the first and second capacitance electrodes.

5. A capacitance type sensor comprising:
a substrate;
a detective member that receives an external force;
a first capacitance electrode provided on one surface of the substrate;
a second capacitance electrode provided on the other surface of the substrate;
a first switch electrode provided on the one surface of the substrate and being kept at a ground or another fixed potential;
a second switch electrode provided on the other surface of the substrate and being kept at the ground or another fixed potential;
a first conductive member disposed on the one surface side of the substrate so as to be distant from the first switch electrode and kept in an insulated state, the first conductive member cooperating with the first capacitance electrode to form a first capacitive element; and
a second conductive member disposed on the other surface side of the substrate so as to be distant from the second switch electrode and kept in an insulated state, the second conductive member cooperating with the second capacitance electrode to form a second capacitive element,
one of the distance between the first capacitance electrode and the first conductive member and the distance between the second capacitance electrode and the second conductive member increasing while the other decreases, and one of a state in which the first conductive member comes into contact with the first switch electrode and a state in which the second conductive member comes into contact with the second switch electrode being able to appear, when the detective member is displaced perpendicularly to the first substrate,
the displacement of the detective member being able to be recognized on the basis of detection of a change in the capacitance value of at least one of the first and second capacitive elements by using signals input to the first and second capacitance electrodes.

6. The capacitance type sensor according to claim 5, wherein the first and second conductive members are electrically connected to each other.
